(19) United States
(12) Patent Application Publication
(10) Pub. No.: US 2019/0302156 A1
(43) Pub. Date: Oct. 3, 2019

(54) APPARATUS AND CLOUD SERVER MONITORING ENERGY CONSUMPTION

(71) Applicant: LG ELECTRONICS INC., Seoul (KR)

(72) Inventors: Sang Won KIM, Seoul (KR); Seunghoe CHOE, Seoul (KR)

(73) Assignee: LG ELECTRONICS INC., Seoul (KR)

(21) Appl. No.: 16/368,667

(22) Filed: Mar. 28, 2019

(30) Foreign Application Priority Data
Mar. 29, 2018 (KR) 10-2018-0036884

(51) Int. Cl. G01R 22/06; H04L 12/28; H02J 3/14

(52) U.S. Cl. CPC G01R 22/06; H04L 12/2827; H04L 12/2825; H02J 2003/143; H04L 12/2838; H04L 2012/2841; H02J 3/14

(57) ABSTRACT

A wireless power sensing apparatus can include a measuring unit configured to measure power consumption corresponding to a plurality of devices located within a target space; a central controller configured to calculate accumulated energy consumption per unit time by accumulating the power consumption measured by the measuring unit in a predetermined unit of time, and calculate individual energy consumption of one or more devices among the plurality of devices based on the accumulated energy consumption; and a communication unit configured to transmit the individual energy consumption of the one or more devices to an external device.

### CROSS-REFERENCE TO RELATED APPLICATION

This application claims priority to and the benefit of Korean Patent Application No. 10-2018-0036884, filed in the Republic of Korea on Mar. 29, 2018, the disclosure of which is incorporated herein by reference in its entirety.

### BACKGROUND

### 1. Field of the Invention

An apparatus and a cloud server that monitor energy consumption are disclosed herein.

### 2. Description of Related Art

Home appliances provide energy saving in various ways, but there is a limitation to a clear confirmation of consumers with respect to the energy saving of the home appliance. Power consumed by the home appliances may not be constant depending on performance and operating conditions of an apparatus, and determining how much power of each apparatus consumes may enable controlling a use pattern of an entire electronic product.

An apparatus, such as a smart plug, to which individual apparatuses are connected, is installed and used to determine the power consumption of these apparatuses. However, convenience of use is not ensured because a separate smart plug may be provided for each individual apparatus or for each individual outlet.

In this regard, Korean Patent No. 10-1555942 discloses a configuration in which a measuring apparatus is integrally coupled to an inside of a distribution panel, as an apparatus of measuring energy. However, this configuration does not provide any algorithm to identify the unique energy consumption of a particular device and only enables identification of changes in the total energy consumption.

Therefore, a method of monitoring a state of total energy consumption in the house without having to couple a dedicated smart plug to every single apparatus is desired to more easily determine the total power consumption and individual power consumptions of multiple apparatuses. Thus, the present disclosure provides a method capable of determining a state of the power use of multiple apparatuses more effectively.

### SUMMARY OF THE INVENTION

The present disclosure solves the above-mentioned problems. The present disclosure provides a method of accumulating energy consumption and sampling the accumulated energy consumption to effectively identify information on power consumption of apparatuses.

The present disclosure further determines energy consumption of an apparatus using an inflection point in a waveform of energy consumption to increase accuracy thereof when information on the power consumption of the apparatuses is collected and the power consumption of the apparatuses is determined.

The objects of the present disclosure are not limited to the above-mentioned objects, and other objects and advantages of the present disclosure which are not mentioned can be understood by the following description and more clearly understood based on the embodiments of the present disclosure. It will also be readily understood that the objects and the advantages of the present disclosure may be realized by the means defined in claims and a combination thereof.

According to an embodiment of the present disclosure, a wireless power sensing apparatus includes a central controller that calculates accumulated energy consumption per unit time of the apparatus by accumulating the power consumption of the apparatuses measured by a measuring unit that measures the power consumption in a constant unit of time and calculates individual energy consumption of one or more of apparatuses based on the accumulated energy consumption of the apparatus.

According to an implementation of the present disclosure, the central controller of the wireless power sensing apparatus analyzes changes in the energy consumption during a predetermined sampling period based on an energy use pattern of the apparatus, and calculates the individual energy consumption of the apparatus.

According to an embodiment of the present disclosure, a cloud server includes a server controller that calculates individual energy consumption of one or more apparatuses based on accumulated energy consumption for each wireless power sensing apparatus, received by a communication unit.

According to an embodiment of the present disclosure, the server controller of the cloud server compares changes in the energy consumption during a predetermined sampling period based on the energy use pattern of the apparatus and calculates the individual energy consumption of each apparatus.

When embodiments of the present disclosure are applied, it is possible to determine the power consumption of each apparatus among multiple apparatuses in buildings by installing an apparatus of sensing energy consumption in the distribution panel.

Further, when embodiments of the present disclosure are applied, it is possible to determine the power consumption of each of the home appliances in real time.

Further, when embodiments of the present disclosure are applied, it is possible to save the energy by remotely monitoring the power consumption of the home appliances.

The effects of the present disclosure are not limited to the effects described above, and those skilled in the art of the present disclosure can readily understand various effects obtained by the present disclosure based on the specific description of the present disclosure.

### BRIEF DESCRIPTION OF THE DRAWINGS

FIG. 1 shows a configuration of a wireless power sensing apparatus according to an embodiment of the present disclosure.

FIG. 2 shows a configuration of a wireless power sensing apparatus and other home appliances according to an embodiment of the present disclosure.

FIG. 3 shows a configuration in which a central controller determines energy consumption according to an embodiment of the present disclosure.

FIG. 4 shows a configuration in which a cloud server determines energy consumption according to an embodiment of the present disclosure.

FIG. 5 is a graph illustrating accumulation of energy consumption according to an embodiment of the present disclosure.

FIG. 6 shows a process of calculating individual energy consumption of multiple apparatuses based on energy use patterns and changes in accumulated energy consumption according to an embodiment of the present disclosure.

FIG. 7 shows a process of calculating individual energy consumption of a new apparatus using energy consumption of a product which is determined in the past, according to an embodiment of the present disclosure.

FIG. 8 shows interactions between a cloud server, a wireless power sensing apparatus, and optionally a smart device according to an embodiment of the present disclosure.

### DETAILED DESCRIPTION OF EMBODIMENTS

Hereinafter, embodiments of the present disclosure will be described in detail with reference to the drawings so that those skilled in the art to which the present disclosure pertains can easily implement the present disclosure. The present disclosure may be implemented in many different manners and is not limited to the embodiments described herein.

In order to clearly illustrate the present disclosure, technical explanation that is not directly related to the present disclosure may be omitted, and same or similar components are denoted by a same reference numeral throughout the specification. Further, some embodiments of the present disclosure will be described in detail with reference to the drawings. In adding reference numerals to components of each drawing, the same components may have the same reference numeral as possible even if they are displayed on different drawings. Further, in describing the present disclosure, a detailed description of related known configurations and functions will be omitted when it is determined that it may obscure the gist of the present disclosure.

In describing components of the present disclosure, it is possible to use the terms such as first, second, A, B, (a), and (b), etc. These terms are only intended to distinguish a component from another component, and a nature, an order, a sequence, or the number of the corresponding components are not limited by that term. When a component is described as being “connected,” “coupled” or “connected” to another component, the component may be directly connected or able to be connected to the other component; however, it is also to be understood that an additional component may be “interposed” between the two components, or the two components may be “connected,” “coupled” or “connected” through an additional component.

Further, with respect to embodiments of the present disclosure, for convenience of explanation, the present disclosure may be described by subdividing an individual component, but the components of the present disclosure may be implemented within a device or a module, or a component of the present disclosure may be implemented by being divided into a plurality of devices or modules.

Identifying the power consumption used by a plurality of electronic apparatuses in a building or in a house, for example, home appliances, communication apparatuses, and the like, may be considered as a method of saving electricity when the electronic products are used. However, it is possible to sense both the power consumption and an amount of current in the building or in the house and calculate the power consumption and the amount of the current to accurately determine the power consumption for each electronic apparatus among a plurality of electronic apparatuses.

In the present disclosure, a configuration in which a smart power meter apparatus that generates information on the used power consumption is installed in a distribution panel so that energy consumption in a building can be determined will be described. In the present disclosure, a sensor (a sensing unit) of a current transformer (CT) is arranged in the distribution panel to sense the information on the power consumption.

In one embodiment, the smart power meter apparatus including the sensor of the CT senses a current value and multiplies the current value by a fixed voltage value of the supplied power, and transmits the multiplied value to the cloud server. The cloud server may determine the types of the apparatuses and a magnitude of the energy used by the apparatuses using the power value received from the smart power meter apparatus and parameters stored in a database.

Hereinafter, a target space where a plurality of electronic apparatuses are arranged in the target space, such as in a building or in a house, to sense power consumption is referred to as “a sensing space.” Further, an apparatus that is arranged in the distributing panel to supply the power to the sensing space to perform smart power metering, that is, a smart power meter apparatus is an example of a component of the present disclosure and is referred to as “a wireless power sensing apparatus” in the present disclosure. The wireless power sensing apparatus can communicate with the outside wirelessly.

In the present disclosure, a state (On/Off) of a main product of consuming energy in the sensing space and the energy consumption can be automatically determined and confirmed based on information on total energy consumption obtained from the wireless power sensing apparatus installed in the distribution panel. The wireless power sensing apparatus automatically determines the turn-on (On) state of the main product that is consuming a majority of the energy (e.g. in summer: an air conditioner and in winter: an electric heater), and provides the user with information on the use state of the main product that is consuming the energy (notification information).

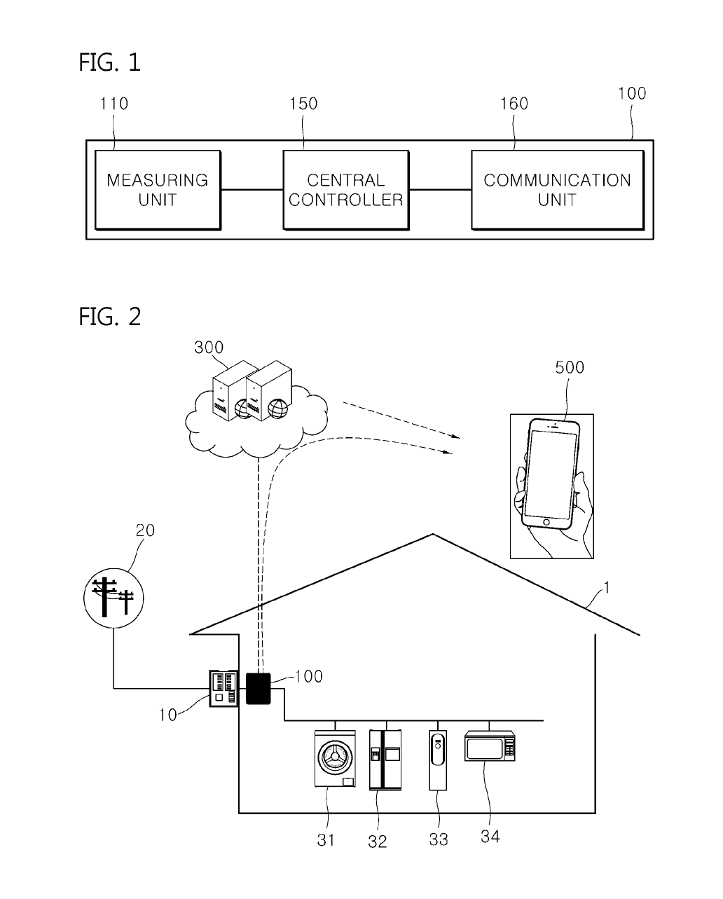

FIG. 1 shows a configuration of a wireless power sensing apparatus according to an embodiment of the present disclosure. A wireless power sensing apparatus 100 includes a measuring unit 110 that measures power consumption by sensing a change or a state of electric energy supplied to the house through a distribution panel and a central controller 150 that is configured such that the types of products are determined based on the accumulated value after performing sampling of information on the measured state for a certain amount of time and accumulating the information, or the central controller 150 is configured to transform the accumulated value for transmitting to a cloud apparatus.

The central controller 150 calculates the accumulated energy consumption per unit time by accumulating the power consumption measured by the measuring unit 110 at a predetermined unit of time, and calculates the individual energy consumption of one or more apparatuses based on the accumulated energy consumption. The central controller 150 calculates the individual energy consumption of one or more apparatuses based on an inflection point produced when a change in the accumulated energy consumption occurs.

The wireless power sensing apparatus 100 further includes a communication unit 160 that transmits a result, to an external smart device, determined by the central controller 150 or the cloud apparatus, that is, the individual energy consumption of one or more apparatuses calculated by the central controller 150.

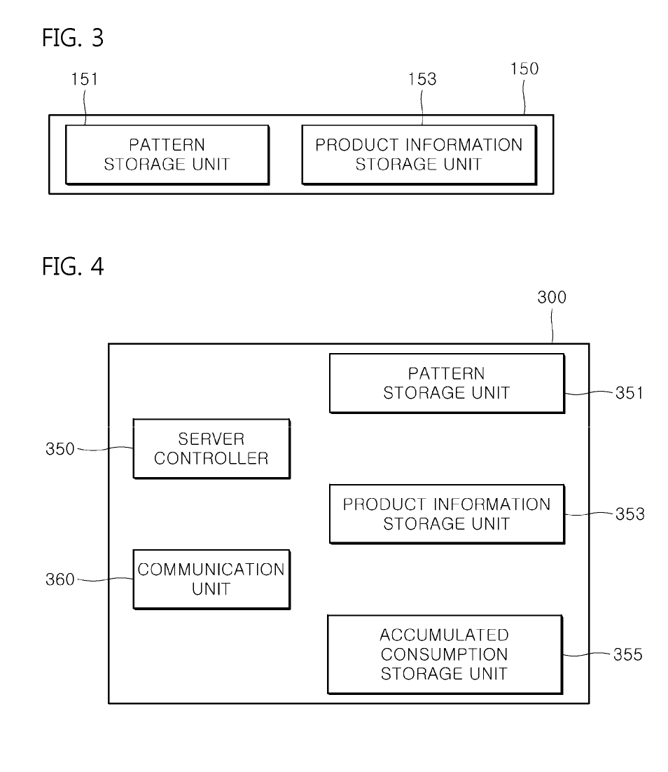

The communication unit 160 can directly or indirectly transmit the value converted by the central controller 150 to the cloud apparatus. The communication unit 160 can communicate with the external apparatuses based on Wi-Fi, but can also be configured to communicate with the external apparatuses through a mobile communication protocol. That is, the communication unit 160 can exchange information with the external apparatuses through various types of communication protocols, and receive data for upgrading software in the central controller 150 from the external cloud server 300. The communication unit 160 can receive the data, from the external cloud server 300, in a pattern storage unit 151 or a product information storage unit 153 of FIG. 3 described below.

According to an embodiment of the present disclosure, the measuring unit 110 can measure a current value by generating induction power. That is, the measuring unit 110 can be installed adjacent to an electric wire in the distribution panel, and the measuring unit 110 can generate the current value by sensing the current.

The central controller 150 calculates the total amount of electric energy used based on the information on the change or the state of the electric energy measured by the measuring unit 110. The total consumption refers to a total amount of energy used by the electronic apparatuses arranged in the sensing space. In one embodiment, the central controller 150 can calculate the power value by multiplying the current value calculated by the measuring unit 110 by a supplied voltage of the electric wire and accumulate and store the calculated current value therein.

The central controller 150 can additionally execute an application. This application can provide functions for the central controller 150 to determine the energy consumption or to provide the user with notification service.

According to an embodiment of the present disclosure, the wireless power sensing apparatus 100 can sense the current value. As the current value and the power value derived from the current value continuously vary, the central controller 150 accumulates and stores the current value and the power value derived from the current value in a predetermined unit of time, and generates the current value and the power value derived from the current value as a compressed power value. For example, if the unit of time is 1 second, a start power value for 1 second and a changed value after 1 second can be accumulated and compressed. Then, the compressed value can be accumulated again during the sampling period and the compressed value can be confirmed as the power value for 10 minutes or 15 minutes.

FIG. 2 shows a configuration of a wireless power sensing apparatus and other home appliances according to an embodiment of the present disclosure in detail.

Electric energy provided by a power company 20 is supplied to a plurality of home appliances 31, 32, 33 and 34 through a distribution panel 10 of a building 1. The wireless power sensing apparatus 100 can be arranged in the distribution panel 10 or adjacent to the distribution panel 10. The wireless power sensing apparatus 100 monitors a use state of electricity generated by using the home appliances 31, 32, 33 and 34 in the building 1 and determines the types of products and/or transmits the information on the use state of the electricity monitored to a cloud server 300 so that the cloud server 300 determines the individual types of products and the energy consumption of each individual product based on the information on the use state of the electricity.

Further, the result of the determination of the use state of the product can be confirmed on a screen of a smart device 500 by the cloud server 300 or the wireless power sensing apparatus 100.

A smart device 500 can communicate with external apparatuses using Wi-Fi (wireless LAN) or Bluetooth communication and the examples of the smart apparatus 500 can include a smart phone, a tablet computer, and a home automation apparatus, and the like. It is possible to determine the power consumption for each apparatus among a plurality of apparatuses within the target space, which is transmitted by the wireless power sensing apparatus 100 or the cloud server 300 on the screen of these types of communication apparatuses. Further, the smart device 500 outputs the information of the apparatuses sensed by the wireless power sensing apparatus 100, based on the provided information, so that the user identifies the output information.

In the configuration as shown in FIG. 2, a separate smart plug is not installed for each of the home appliances 31, 32, 33 and 34. However, it is possible to automatically determine the state and the power consumption of the main product that is consuming a majority of the energy based only on the information on the total consumption sensed by the wireless power sensing apparatus 100.

In one embodiment, information on use (the state and the power consumption) of the main product of consuming the energy per unit time (hour, day, month) can be monitored and the monitored information on use can be output to or through the smart device 500.

The wireless power sensing apparatus 100 accumulates and performs sampling of the total energy consumption in the building 1 during a predetermined sampling period (e.g., 1 minute, 10 minutes, or 15 minutes, and the like). When a feature value is extracted from these sampling values, as the sampling period is used, and the feature value can be extracted from the accumulated value instead of an instantaneous value. The feature value is used as a standard for determining which apparatus has started operating or stopped operating using an increase or decrease of accumulated information on the power consumption during a certain period and the magnitude (changed value) of the increased or decreased power consumption.

When the configurations as shown in FIGS. 1 and 2 are applied, if the accumulated value during the certain period (e.g., an accumulated value obtained during a period of 15 minutes) is greater than a total accumulated average value (e.g., an average value obtained per unit of 12 hours), the air conditioner may be determined to be turned on as an example of determining a situation in which a home appliance having greater power consumption, such as the air conditioner, is turned on. Further, in this process, the product can be determined by reflecting characteristics of a sensing time point (e.g., summer, winter, day, night, and the like). The total accumulated average value can be calculated in various ways, such as, 6 hours or 3 hours, in addition to 12 hours. The central controller 150 can manage and calculate two or more total accumulated average values to determine the types of the apparatuses.

When the configurations shown in FIGS. 1 and 2 are applied, it is possible to automatically determine the state of the main product that is consuming a majority of the energy, a highest amount of energy, or a large amount of energy, that is, the power consumption, without installing a separate smart plug dedicated solely to the main product, so that the user can be notified of the information on using of the product with respect to the energy consumption of the main product through the smart device 500. The main product or main products includes electronic products that consume a large amount of energy and the examples of the main product can include an air conditioner, a refrigerator, and the like. Particularly, as the products such as the air conditioner are used in certain seasons and the product such as the air conditioners uses a large amount of energy during a short period of time, it is desired for the users to provide a method capable of determining the energy consumption.

FIG. 3 shows a configuration in which a central controller determines energy consumption according to an embodiment of the present disclosure.

The central controller 150 includes a pattern storage unit 151 that stores information on the energy use pattern of each product and a product information storage unit 152 that stores information (identification information or classification information, and the like) on the home appliances arranged in the house.

The pattern storage unit 151 stores information on energy use pattern of the apparatus or apparatuses. That is, the pattern storage unit 151 stores information on the energy use pattern of each particular apparatus (e.g. the refrigerator, the air conditioner, and the like) and the types of and information on each particular product. For example, an energy use pattern of an electronic product (a product used for a long period of time) that is operated for a predetermined time or more, such as an air conditioner, a washing machine, a refrigerator or an electric rice cooker may be different from the energy use pattern of another electronic product (a product used for a short period of time) that is operated for a short period of time, such as a heater, a cleaner, a dryer, a microwave oven, and the like. These types of patterns are separately stored in the pattern storage unit 151.

Further, a pattern of a product in which the energy consumption changes during the use thereof can be distinguished from the pattern of another product that is turned on and off after a predetermined amount of energy is used. The patterns stored in the pattern storage unit 151 can be generated and stored for each product in advance. As a result, when a peak value occurs or a change of which occurs in a use flow of the total energy, the energy consumption of the particular product can be determined by comparing a changed pattern with the patterns stored in the pattern storage unit 151. The central controller 150 compares the changed pattern of current sensing and stored patterns, and the central controller 150 determines the type of apparatus which made the change of current or made the changed pattern.

The pattern storage unit 151 can store specific seasonal factors or temporal factors together. For example, in the air conditioner, information on use, such as summer, daytime, and the like can be set.

In one embodiment, the product information storage unit 153 stores identification information of the home appliances, by the user, arranged in the space. Further, the product information storage unit can store not only the identification information but also information on the power consumption of the home appliance, that is, information on energy use of the product. The information on energy use includes basic data that can be used to estimate energy consumption, such as average energy consumption of the product and/or maximum energy consumption of the product.

Alternatively, a module that transmits the identification information to the wireless power sensing apparatus thereto is mounted on the home appliance, the product information storage unit 153 receives and stores the identification information from the home appliance at a time point when the product is arranged and the product is initially operated, or a time point at which the product is turned on and the wireless power sensing apparatus can accurately determine the energy consumption of the product based on the identification information. The detailed model name of the home appliance is an example of the identification information of the home appliance. Further, an example of the identification information of the home appliances can include information on the types of the home appliances (a heater, a dryer, a refrigerator, an air conditioner, and the like).

As shown in FIG. 3, the central controller 150 can enhance accuracy of identification of the apparatus based on the information stored in the pattern storage unit 151 and the product information storage unit 153. The identification accuracy of the apparatus is enhanced using information on a feature of the power consumption used by each apparatus (e.g., a feature or function that is unique to a specific home appliance), or a duration of power use for each apparatus, and time of use of the apparatus.

FIG. 4 shows a configuration in which a cloud server determines energy consumption according to an embodiment of the present disclosure. The cloud server receives accumulated energy consumption from a plurality of wireless power sensing apparatuses for a certain time. The energy consumption of the main product can be determined based on changes or a magnitude of the energy consumption received from the plurality of wireless power sensing apparatuses.

The cloud server 300 includes a pattern storage unit 351 that stores information on an energy use pattern of a product, a product information storage unit 353 that stores information on products sensed by the wireless power sensing apparatuses, an accumulated consumption storage unit 355 that stores information on the previously accumulated energy consumption for each sensing apparatus, a server controller 350 that controls these components, and a communication unit 360.

The pattern storage unit 351 can have the same or similar configuration as the pattern storage unit 151 of the wireless power sensing apparatus 100 as shown in FIG. 3 in the above. The product information storage unit 353 stores the product information together with the identification information of the wireless power sensing apparatuses, and when the server controller 350 determines the energy consumption of the main product based on the accumulated value of the energy consumption provided by the wireless power sensing apparatus, the stored information can be used as a reference data.

Similarly, the accumulated consumption storage unit 355 stores the information on the energy consumption received from each wireless power sensing apparatus 100 during a predetermined period together with the identification information of the wireless power sensing apparatuses, so that the server controller 350 can check the change in the energy consumption in the target space where each of the wireless power sensing apparatuses 100 sense energy consumption.

The cloud server 300 can refer to information on energy consumption of other buildings stored in the accumulated consumption storage unit 355. For example, the accumulated energy consumption of the apparatuses arranged in the first building and the accumulated energy consumption of the apparatuses arranged in the second building are stored in the accumulated consumption storage unit 355. Further, the information on the apparatus in the first building is identified.

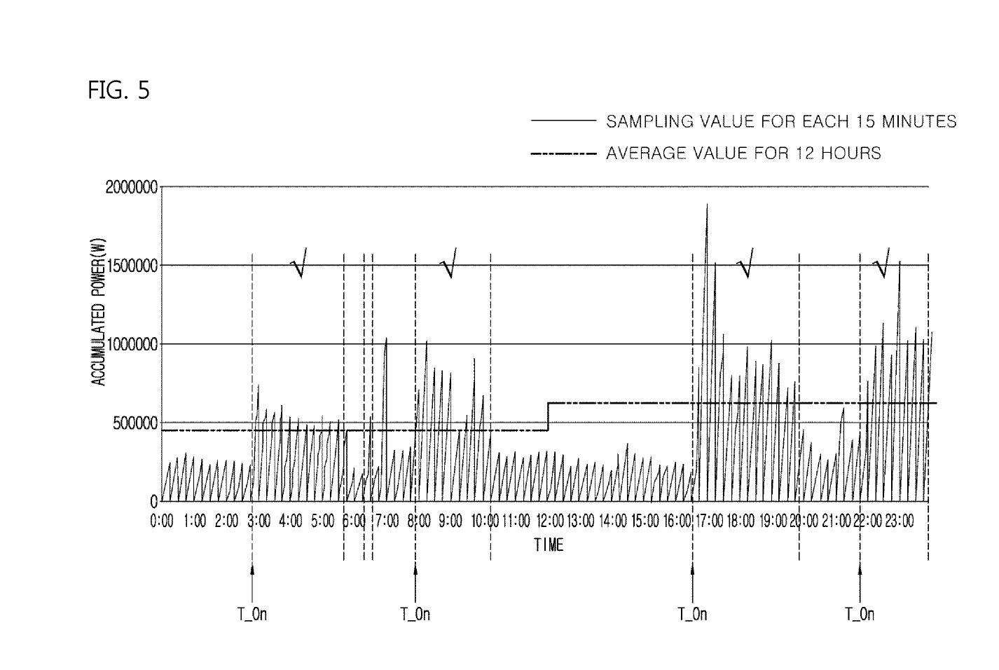

The server controller 350 can search for a pattern of energy consumption of the first building, which is the same as the pattern of energy consumption of the second building. The pattern of the energy consumption of the first building can be determined based on a point at which the inflection point of the accumulated energy consumption thereof occurs for each sampling period and a magnitude of the energy consumption that is increased or decreased at the inflection point thereof, which will be described in FIG. 5. If the energy consumption pattern of the first building and the energy consumption pattern of the second building are overlapped with each other during a predetermined period of time by analyzing and comparing the magnitude (the energy consumption caused by the operation of the particular apparatus), the information on the apparatus identified in the first building can be used (e.g., stored patterns for devices that have already been properly identified in one building can be used to identify devices in another building, which has the same or similar energy use patterns).

For example, when the server controller 350 turns on the air conditioner in the first building, and the pattern of the energy consumption generated from the first building is identical or nearly identical to the pattern of the energy consumption generated from the second building, it may be confirmed that the same type of air conditioner or appliance is turned on in the second building.

FIG. 5 is a graph showing accumulation of energy consumption according to an embodiment of the present disclosure. FIG. 5 shows the accumulated power consumption during a certain sampling period (e.g. a sample for every 15 minutes), determined by the central controller 150 of the wireless power sensing apparatus or the server controller 350 of the cloud server 300 in the graph.

The central controller 150 or the server controller 350 can determine a period for which the air conditioner is used by means of the change in energy consumption of the total consumption based on a pattern in which a specific product, for example, an air conditioner, uses energy. For example, the power consumption was significantly increased in sections marked with checks in FIG. 5 compared to the pattern generated before that period of increased power use.

The central controller 150 or the server controller 350 determines that the energy consumption has increased based on a temperature at a current time point and season information and calculates the energy consumption of the product (the air conditioner) based on increased duration. Information on energy consumption of the air conditioner of the total energy consumption can be transmitted to an external smart device. Alternatively, the cloud server 300 can notify the wireless power sensing apparatus 100 of information on the types of the product (the air conditioner) and the energy consumption.

The central controller 150 or the server controller 350 can confirm changes in the energy consumption per unit time. For example, as shown in FIG. 5, the central controller 150 or the server controller 350 can confirm the changes in the energy consumption for a certain unit of time (e.g. 5 minutes or 15 minutes, and the like), as a sampling period, for the total energy consumption that is continuously measured. In this instance, when the electronic product temporarily uses the energy, a peak may occur during a short period of time. When the generated peak may be accumulated in the unit of time, such a peak may be eliminated. Thus, it is possible to correctly confirm the pattern generated when the electronic product is actually used.

That is, as shown in FIG. 5, it is possible to accumulate the energy consumption during a certain sampling period (a magnitude in which two or more apparatuses are not turned on at the same time or a period for which the feature of using the accumulated electric energy can be extracted when the user uses the electricity in the house for 5 minutes, 10 minutes, or 15 minutes, and the like) and confirm a turn-on state of a particular electronic device (for example, an air conditioner, an electric heater, and the like) based on the information on the accumulated energy consumption, and identify the information on the energy consumption for each apparatus based on the information on turn-on state of the particular electronic device.

In addition, according to an embodiment of the present disclosure, the central controller can have a fixed sampling period, or can set the sampling period to be variable. For example, as a result of comparing the accumulated sampling periods, accumulating the sampling period every 5 minutes enables the energy consumption of the apparatuses to be determined more accurately.

Thus, the central controller 150 can have the two sampling periods at a predetermined time point, for example, once a week or once a month and performs the sampling during a first period (e.g., an interval of 5 minutes), and performs the sampling during a second period (e.g., an interval of 15 minutes). The central controller 150 can select a sampling period adequate for determining the energy consumption of the apparatus more accurately of the two sampling periods. Selecting the sampling period for which the largest change in energy occurs is an example of accurately determining the energy consumption of the apparatus. That is, the central controller 150 can select a period for which a difference between the energy consumption measured during the first sampling period and energy consumption measured during the second sampling period after the first sampling period is significantly generated.

In one embodiment, when the sampling is performed at intervals of 5 minutes, a deviation of the energy use for each period is dif0, and when the sampling is performed at intervals of 15 minutes, a deviation of the energy use for each period is dif1. The central controller 150 can compare the magnitude of the dif0 with the magnitude of the dif1, of the accumulated energy consumption for each period in order to select the period for which the difference between the magnitude of the dif0 and the magnitude of the dif1 is significantly generated. This selection means reflecting the pattern of the energy consumption that is increased or decreased for each period.

Table 1 shows a difference between energy consumption during one sampling period and energy consumption during another period, of two or more periods, according to an embodiment of the present disclosure. In the situation of the period of 5 minutes, the energy consumption during the 5 minute period 1-3 (47) was increased by 22 than the energy consumption (25) during the 5 minute period 1-2. The energy consumption during period 1-3 was increased by 88% (22/25) based on the energy consumption during period 1-2.

Further, in the situation of the period of 15 minutes (e.g., across 2-1, 2-2 and 2-3), the energy consumption (162) during the second period was increased by 63 compared to the energy consumption (99) during the first period, and the energy consumption during the second period was increased by 63% (63/99) compared to the energy consumption during the first period. Thus, as shown in Table 1, the central controller 150 can use 5 minutes as a sampling period to more accurately determine the difference between the energy consumption during one period and the energy consumption during another period of the two or more periods.

TABLE 1

| | First period | | | Second period | | |
|---|---|---|---|---|---|---|
| | 1-1 | 1-2 | 1-3 | 2-1 | 2-2 | 2-3 |
| Accumulated amount | 27 | 25 | 47 | 53 | 57 | 52 |
| during period of 5 minutes | | | | | | |

| | | |
|---|---|---|
| Accumulated amount | 99 | 162 |
| during period of 15 minutes | | |

On the other hand, as shown in Table 2, in the situation of using a sampling period of 5 minutes, there is no large difference between the energy consumption during one period and the energy consumption during another period of the first and second periods. The difference between the energy consumption during one period and the energy consumption during another period is not generated by 10 or more. On the other hand, the central controller 150 can use the period of 15 minutes as a sampling period to more easily identify the difference between the energy consumption during the first period and the energy consumption during the second period as the difference between the energy consumption during the first period and the energy consumption during the second period is significantly generated by 63%.

TABLE 2

| | First period | | | Second period | | |
|---|---|---|---|---|---|---|
| | 1-1 | 1-2 | 1-3 | 2-1 | 2-2 | 2-3 |
| Accumulated amount | 31 | 35 | 33 | 45 | 57 | 60 |
| during period of 5 minutes | | | | | | |

| | | |
|---|---|---|
| Accumulated amount | 99 | 162 |
| during period of 15 minutes | | |

In summary, the central controller 150 can generate two kinds of the power consumption measured by the measuring unit 110 based on two or more different sampling periods from each other. The central controller 150 can set the sampling period for which the greatest difference between the accumulated energy consumption during one sampling period and the accumulated energy consumption during another sampling period, of the two or more sampling periods, is generated as a sampling period.

As shown in FIG. 5, the energy consumption of the air conditioner can be calculated by comparing the energy consumption of the air conditioner at a time point (T_On) when the air conditioner is turned on with the previous energy consumption of the air conditioner and reflecting this difference between the energy consumption of the air conditioner at a time point (T_On) when the air conditioner is turned on with the previous energy consumption of the air conditioner. This step will be described in more detail.

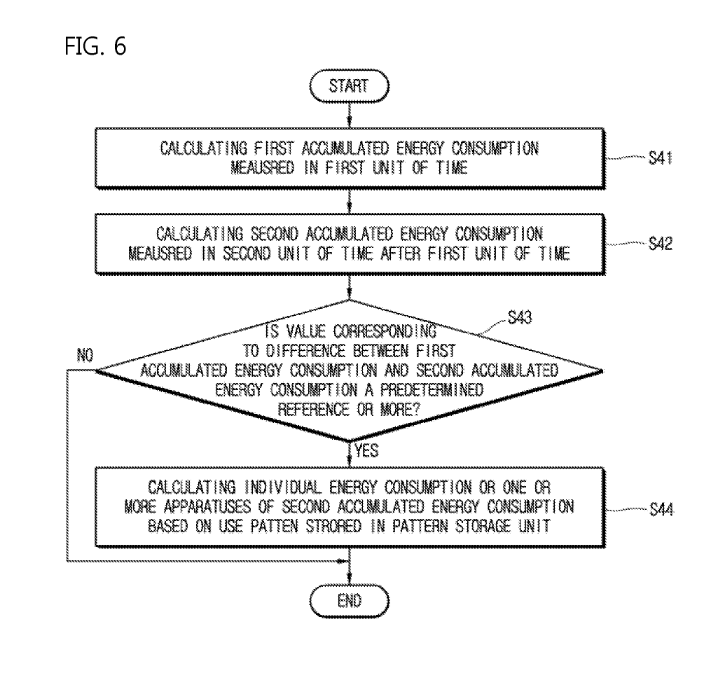

FIG. 6 shows a process of calculating individual energy consumption of an apparatus based on an energy use pattern and changes in accumulated energy consumption according to an embodiment of the present disclosure. The process as shown in FIG. 6 can be applied to both the central controller 150 and the server controller 350. For convenience of explanation, the central controller 15 may be mainly described, but the embodiment in FIG. 6 can be applied to the server controller 350 of the cloud server 300.

The central controller 150 calculates the first accumulated energy consumption measured in the first unit of time (S41). Then, the central controller 150 calculates second accumulated energy consumption measured in a second unit of time after the first unit of time (S42).

As shown in FIG. 5, the accumulated energy consumption is continuously calculated at time intervals of every 15 minutes. Then, the central controller 150 compares the newly accumulated energy consumption with the accumulated energy consumption in the previous unit of time when newly accumulated energy consumption is calculated. That is, when the difference between the first accumulated energy consumption and the second accumulated energy consumption is greater than a predetermined reference (S43), the central controller 150 determines that the home appliance is turned on or off, and calculates the individual energy consumption, of one or more apparatuses, of the second accumulated energy consumption based on the use pattern stored in the pattern storage unit (S44).

In more detail, as shown in FIG. 5, if the accumulated energy consumption is rapidly increased at a time point of 3:00 by a predetermined level or more, the central controller 150 compares the increased pattern with the use patterns stored in the pattern storage unit 151. This kind of information can be continuously accumulated and information on a time point of 6:00 at which the accumulated energy consumption is rapidly decreased can also be collected, and the central controller 150 can determine that the air conditioner is turned on and then turned off, and can calculate an amount of the energy used by the air conditioner during that time. For example, in this way, the amount of energy used by the just the air conditioner can be isolated from among the total energy consumption of the target space.

As shown in FIG. 6, the central controller 150 can calculate the individual energy consumption by reflecting information on energy use (e.g., maximum energy consumption, minimum energy consumption, energy consumption calculated when the apparatus is turned on) of the product stored in the product information storage unit 153 in the calculation of the individual energy consumption of one or more apparatuses (S44).

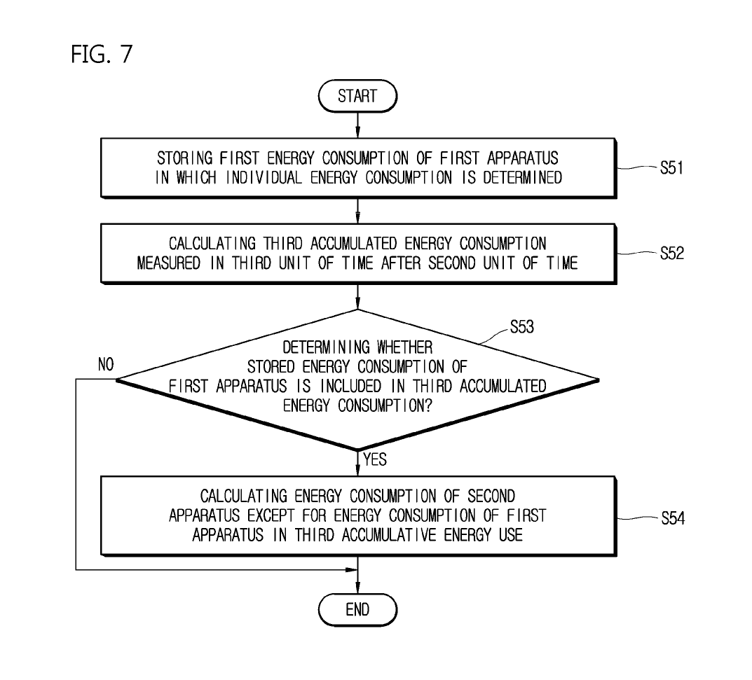

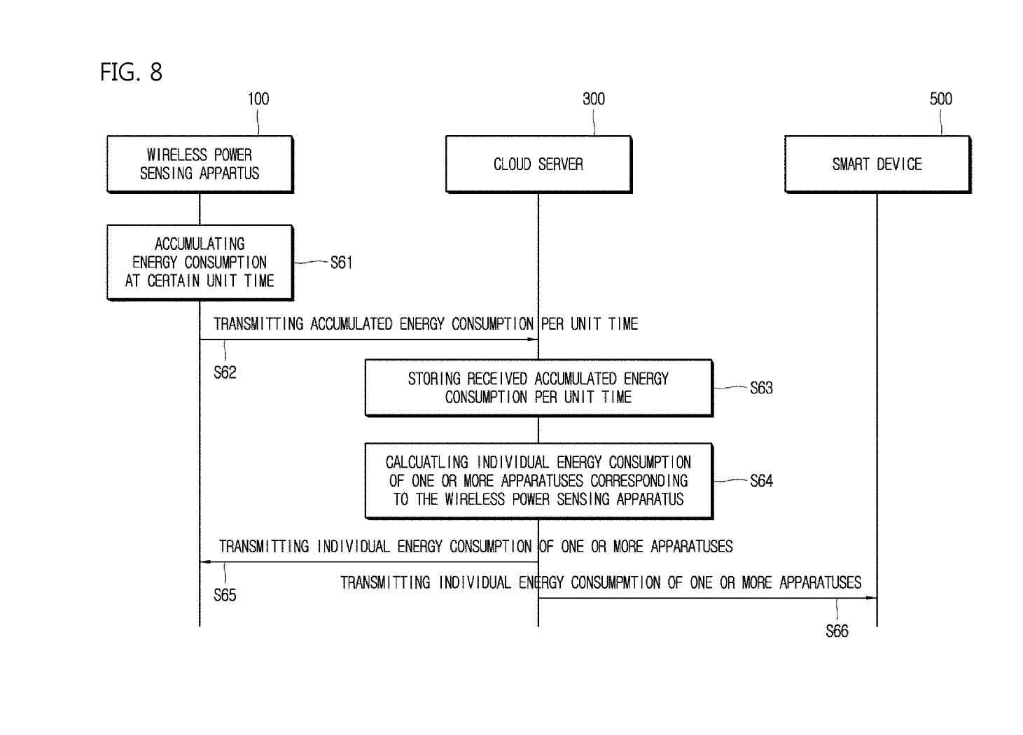

In more detail, in S44, it is identified whether the accumulated energy consumption is made by one product, or two or more products. This will be described in more detail in FIG. 7.

FIG. 7 shows a process of calculating individual energy consumption of a new apparatus using energy consumption of a product determined in the past according to an embodiment of the present disclosure.

The steps of FIG. 7 can be applied to both the central controller 150 and the server controller 350. For convenience of explanation, the central controller 150 will be mainly described, but the example of FIG. 7 can be applied to the server controller 350 of the cloud server 300.

The central controller 150 stores the energy consumption of the first apparatus whose individual energy consumption has been determined. For example, when the air conditioner is determined as the first apparatus, the energy consumption of the air conditioner (the energy consumption of the first apparatus) is stored (S51).

Then, the central controller 150 calculates third accumulated energy consumption, measured in a third unit of time, after the second unit of time (S52). The central controller 150 determines whether the stored energy consumption of the first apparatus is included in the third accumulated energy consumption (S53). If it is determined that the stored energy consumption of the first apparatus is included in the third accumulated energy consumption, the central controller 150 calculates the energy consumption of the second apparatus except for the energy consumption of the first apparatus, out of the third accumulated energy consumption.

For example, if the energy consumption of the air conditioner (e.g., the energy consumption of the first apparatus) is determined when the air conditioner and the dryer are turned on, the energy consumption of the air conditioner is excluded from the third accumulated energy consumption. Then, the energy consumption (e.g., the energy consumption of the second apparatus) of a dryer (e.g., the second apparatus) is calculated from the remaining amount thereof (S54). For example, in this way, the amount of energy used by the just the dryer can be isolated and identified. The remaining amount is remaining amount of the third accumulated energy consumption after excluding the energy consumption of the air conditioner from the original third accumulated energy consumption.

By repeating this step, the central controller 150 can calculate the energy consumption used by the plurality of apparatuses. Further, base energy consumption can be calculated without determining each energy consumption of apparatuses. This energy consumption can be determined based on a very long time, such as 12 hours or 24 hours. As a result of measuring it for a long time, the lowest accumulated energy consumption per unit time is determined as the base energy consumption. Then, when the accumulated energy consumption per unit time is increased, it is possible to determine the energy consumption of the apparatus except for the base energy consumption.

FIG. 8 shows interactions between a cloud server, a wireless power sensing apparatus, and optionally a smart device according to an embodiment of the present disclosure.

The wireless power sensing apparatus 100 accumulates the energy consumption at a certain unit of time (S61). When the wireless power sensing apparatus 100 accumulates the energy consumption at the certain unit of time, and transmits information on the accumulated energy consumption at a certain unit of time, which is calculated (S62), the communication unit 360 of the cloud server 300 receives the information on the accumulated energy consumption per unit time.

Then, the server controller 350 stores information on the received accumulated energy consumption per unit time together with the identification information of the wireless power sensing apparatus 100 (S63), and calculates the individual energy consumption of one or more apparatuses, for example, a wireless power sensing apparatus, based on the accumulated energy consumption (S63). The step of calculating the energy consumption is described in FIGS. 6 and 7.

The communication unit 300 transmits the calculated individual energy consumption of each of the apparatuses to the wireless power sensing apparatus 100 or the smart device 500. At this time, the smart apparatus 500 can communicate with the external apparatus and output information and include a smart phone, a tablet, a notebook, and the like.

When the embodiments of the present disclosure are applied, it is possible to determine an electric heating product or the product that uses a large amount of energy based on information on the total energy consumption and monitor the energy consumption of the electric heating product or the product that uses a large amount of energy. The wireless power sensing apparatus including a sensor of the CT can be used to determine the energy consumption thereof. The wireless power sensing apparatus or the cloud server can determine the energy consumption of each particular product among a plurality of products located within a target space based on the steps as shown in FIGS. 6 and 7.

Further, this kind of information can be output through the smart device, and can be used by the user to determine a state of the energy use in the house or outdoors, thereby confirming which product or products are causing an excessive use of energy.

Particularly, in the situation of a product that uses a large amount of energy and is operated for a longer time than the above-mentioned unit time (such as 5 minutes or 15 minutes) when the product is operated, such as an air conditioner, a large change may occur in the accumulated value at the unit time when the product is turned on. This change is as shown in FIG. 5.

Accordingly, the central controller 150 or the server controller 350 calculates the accumulated energy consumption per unit time. When the accumulated energy consumption increases, the types of the apparatuses used for the unit time, of the apparatuses that are used for a time greater than the unit time can be determined. Thus, the pattern storage unit 151 can store information on a minimum time and a maximum time at which the apparatus is used, or a shortest time from the time when the apparatus is turned off to the time when the apparatus is turned on again. This kind of information is shown in Table 3. Table 3 shows an example calculation of the minimum time, the maximum time, and the shortest time, and information of various types of apparatuses can be generated and stored in the pattern storage unit 151.

TABLE 3

| | Minimum time at | | Maximum time at | | Shortest time at |
|---|---|---|---|---|---|
| Types | which the | | which the | | which the operation |
| of | apparatus | | apparatus | | of the apparatus |
| apparatus | is used | | is used | | is stopped |
| Air | 15 | minutes | 6 | hours | 1 hours |
| conditioner | | | | | |
| Washing | 20 | minutes | 2 | hours | |
| machine | | | | | |
| Dryer | 3 | minutes | 30 | minutes | |

The shortest time at which the operation of an apparatus is stopped means a time taken to turn on the apparatus after turning off the apparatus, on average, during use of the apparatus (e.g., average idle time between two consecutive uses). The shortest time at which the operation of the apparatus is stopped can be applied when the shortest time does not exceed one day. The shortest time at which the operation of the apparatus is stopped that does not exceed one day can also be calculated on average. This can be used to determine whether the apparatuses are the same apparatus when a similar energy use pattern is confirmed.

Therefore, the central controller 150 or the server controller 350 can determine the energy consumption of each of the individual apparatuses using the information on time at which the energy is continuously used, in addition to a change value of the accumulated measured energy consumption.

As shown in FIG. 5, when an apparatus is newly added or removed, specifically, the inflection point of the waveform can occur during each sampling period. Further, the types of apparatuses can be divided into an apparatus that uses a certain amount of power when the apparatus starts to operate, and an apparatus that increases and decreases the power consumption even after the apparatus is turned on. This kind of information can also be stored in the above-mentioned storage 151.

Further, in FIG. 5, it is possible to determine the On/Off state of the apparatuses at a point when the magnitude of the power consumption is rapidly changed (a point of a vertical line indicated by a dotted line), that is, the inflection point. Therefore, the central controller 150 or the server controller 350 can identify the different types of the apparatuses that are currently using the power based on the inflection point and the previous information on the power consumption of the apparatuses (e.g., the pattern storage unit or the product information storage unit).

Although components included in an embodiment of the present disclosure are described as being combined to one, or as being combined to operate, the present disclosure is not necessarily limited to such an embodiment, and these components can operate by being selectively combined to one or more within the purpose range of the present disclosure. Further, although all of the components can be implemented as an independent hardware, a part or all of each of the components can be selectively combined and implemented as a computer program that has a program module that performs some or all of the functions combined in one or a large amount of hardware. Codes and code segments that form the computer program will be easily deduced by those skilled in the art of the present disclosure. Such a computer program can be stored in a computer readable media that a computer can read, and can be read and implemented by the computer to implement embodiments of the present disclosure. As the storage medium of the computer program, it can include a storage media including a semiconductor recording element, an optical recording media, and a magnetic recording media. Further, a computer program that implements embodiments of the present disclosure can include a program module that is transmitted in real time via an external apparatus.

While the embodiments of the present disclosure are mainly described hereinabove, various changes and modifications can be made within the level of those skilled in the art. Thus, when such changes and modifications do not deviate from the scope of the present disclosure, it will be understood that they are included in the scope of the present disclosure.

What is claimed is:

1. A wireless power sensing apparatus, comprising:
a measuring unit configured to measure power consumption corresponding to a plurality of devices located within a target space;
a central controller configured to:
calculate accumulated energy consumption per unit time by accumulating the power consumption measured by the measuring unit in a predetermined unit of time, and
calculate individual energy consumption of one or more devices among the plurality of devices based on the accumulated energy consumption; and
a communication unit configured to transmit the individual energy consumption of the one or more devices to an external device.

2. The wireless power sensing apparatus of claim 1, wherein the central controller includes a pattern storage unit that stores an energy use pattern of the one or more devices,
wherein the central controller is further configured to:
calculate a first accumulated energy consumption measured in a first unit of time and then calculate a second accumulated energy consumption measured in a second unit of time after the first unit of time,
determine when a difference between the first accumulated energy consumption and the second accumulated energy consumption is more than a predetermined reference amount, and
calculate a first individual energy consumption amount of a first device among the one or more devices during the second unit of time based on the energy use pattern stored in the pattern storage unit.

3. The wireless power sensing apparatus of claim 2, wherein the central controller further includes a product information storage unit that stores identification information and information on energy use of the one or more devices, and
wherein the central controller calculates the first individual energy consumption amount of the first device based on the information on the energy use and the identification information.

4. The wireless power sensing apparatus of claim 2, wherein the central controller stores a first energy consumption pattern corresponding to the first device or a first amount of energy consumption corresponding to the first device, and
wherein the central controller is further configured to:
determine whether the first energy consumption pattern or the first amount of energy consumption is included within a third accumulated energy consumption measured in a third unit of time after the second unit of time, and
in response to determining that the first energy consumption pattern or the first amount of energy consumption is included in the third accumulated energy consumption measured in the third unit of time, calculate a second accumulated energy consumption of a second device, wherein the second accumulated energy consumption excludes an energy consumption component corresponding to the first apparatus within the third accumulated energy consumption.

5. The wireless power sensing apparatus of claim 1, wherein the central controller is further configured to:
generate a first type of power consumption for a same time period measured based on a first sampling period and a second type of power consumption for the same time period measured based on a second sampling period different from the first sampling period, and
sets a sampling period to either the first sampling period or the second sampling period based on which one of the first and second sampling periods generates a larger change in the accumulated energy consumption during the same time period.

6. The wireless power sensing apparatus of claim 1, wherein the target space is a home or a building, and
wherein the wireless power sensing apparatus is configured to be installed within or adjacent to a power distribution panel in the home or the building.

7. The wireless power sensing apparatus of claim 1, wherein the external device is a mobile terminal or a smart phone.

8. The wireless power sensing apparatus of claim 1, wherein the central controller is further configured to:
identify a type of a first device among the plurality of devices based on an inflection point produced when a change in the accumulated energy consumption occurs.

9. The wireless power sensing apparatus of claim 1, wherein the plurality of devices include at least one of an air-conditioning unit, a heater, a refrigerator, a microwave oven, an electric oven, a television, a dryer, or a washing machine.

10. The wireless power sensing apparatus of claim 1, wherein the accumulated energy consumption per unit time is a waveform of energy consumption of the plurality of devices during the predetermined unit of time.

11. A cloud server, comprising:
a communication unit configured to receive, from a wireless power sensing apparatus, an accumulated energy consumption per unit time in a predetermined unit of time corresponding to a plurality of devices located within a target space; and
a server controller configured to:
calculate individual energy consumption of one or more devices among the plurality of devices based on the accumulated energy consumption received from the wireless power sensing apparatus, and
transmit, via the communication unit, the individual energy consumption of the one or more devices to the wireless power sensing apparatus or an external device.

12. The cloud server of claim 11, wherein the server controller includes a pattern storage unit that stores an energy use pattern of the one or more devices,
wherein the server controller is further configured to:
calculate a first accumulated energy consumption measured in a first unit of time and then calculate a second accumulated energy consumption measured in a second unit of time after the first unit of time,
determine when a difference between the first accumulated energy consumption and the second accumulated energy consumption is more than a predetermined reference amount, and
calculate a first individual energy consumption amount of a first device among the one or more devices during the second unit of time based on the energy use pattern stored in the pattern storage unit.

13. The cloud server of claim 12, wherein the server controller further includes a product information storage unit that stores identification information and information on energy use of the one or more devices, and
wherein the server controller calculates the first individual energy consumption amount of the first device based on the information on the energy use and the identification information.

14. The cloud server of claim 12, wherein the server controller stores a first energy consumption pattern corresponding to the first device or a first amount of energy consumption corresponding to the first device, and
wherein the server controller is further configured to:
determine whether the first energy consumption pattern or the first amount of energy consumption is included within a third accumulated energy consumption measured in a third unit of time after the second unit of time, and
in response to determining that the first energy consumption pattern or the first amount of energy consumption is included in the third accumulated energy consumption measured in the third unit of time, calculate a second accumulated energy consumption of a second device, wherein the second accumulated energy consumption excludes an energy consumption component corresponding to the first apparatus within the third accumulated energy consumption.

15. A wireless power sensing apparatus, comprising:
a measuring unit configured to measure power consumption corresponding to a plurality of devices located within a target space;
a controller configured to:
generate accumulated energy consumption information by sampling the power consumption measured by the measuring unit at a first sampling rate during a period of time, and
determine a first individual energy consumption component within the accumulated energy consumption information, the first individual energy consumption component corresponding to a first device among the plurality of devices; and
a wireless communication unit configured to wirelessly transmit the first individual energy consumption to an external device.

16. The wireless power sensing apparatus of claim 15, wherein the controller determines the first individual energy consumption component corresponding to the first device based on an inflection point in the accumulated energy consumption information that is produced when a change in the accumulated energy consumption occurs.

17. The wireless power sensing apparatus of claim 15, wherein the controller determines the energy consumption component corresponding the first device based on a stored energy use pattern, or
wherein the controller determines the energy consumption component corresponding the first device based on a determination of when the power consumption measured by the measuring unit changes by more than a predetermined reference amount between two samples of the power consumption sampled at the first sampling rate.

18. The wireless power sensing apparatus of claim 15, wherein the first device is a main device that consumes a highest amount of energy from among the plurality of devices during the period of time.

19. The wireless power sensing apparatus of claim 15, wherein the controller is further configured to:
remove the first individual energy consumption component corresponding to the first device from the accumulated energy consumption information to generate a remaining amount of the accumulated energy consumption information, and
determine a second individual energy consumption component within the remaining amount of the accumulated energy consumption information, the second individual energy consumption component corresponding to a second device among the plurality of devices.

20. The wireless power sensing apparatus of claim 19, wherein the controller is further configured to:
remove the first individual energy consumption component and the second individual energy consumption component from the accumulated energy consumption information to generate a lessor remaining amount of the accumulated energy consumption information, and
determine a third individual energy consumption component within the lessor remaining amount of the accumulated energy consumption information, the third individual energy consumption component corresponding to a third device among the plurality of devices.
